(19) United States
(12) Patent Application Publication
(10) Pub. No.: US 2026/0190934 A1
(43) Pub. Date: Jul. 2, 2026

(54) VACUUM BAKING MECHANISM WITH BUFFER TREATMENT AND VACUUM BAKING METHOD THEREOF

(71) Applicant: UVAT TECHNOLOGY CO., LTD., Taoyuan City (TW)

(72) Inventors: Yuan-Chi LEE, Taoyuan City (TW); Pin-Chun LIU, Taoyuan City (TW); Ming-Chan TSAI, Taoyuan City (TW); Dai-Wei LIN, Taoyuan City (TW); Keng-Min CHENG, Taoyuan City (TW); Ching-Kai CHIU, Taoyuan City (TW); Cheng-Wei YANG, Taoyuan City (TW); Chin-Nan TSENG, Taoyuan City (TW); Hsu LIN, Taoyuan City (TW)

(21) Appl. No.: 19/002,813

(22) Filed: Dec. 27, 2024

(51) Int. Cl. H01L 21/677; H01L 21/67

(52) U.S. Cl. CPC H10P 72/3304; H10P 72/0434; H10P 72/3312

(57) ABSTRACT

A vacuum baking mechanism with buffer treatment includes a substrate transport station, a first buffer chamber, and a vacuum baking chamber. The substrate transport station includes a transport conveyance module for substrates placing and taking operations. The first buffer chamber includes a first buffer gate, a plurality of first conveyance modules, and a first baking doorway for respectively receiving or outputting each substrate through the first buffer gate or the first baking doorway. The vacuum baking chamber includes a first baking gate connected with the first baking doorway, and a baking module for vacuum baking the substrates. With such configuration, the present disclosure improves the baking efficiency of the vacuum baking chamber and the yield of the substrate processing operation.

### BACKGROUND OF THE DISCLOSURE

### 1. Field of the Disclosure

The present disclosure relates to vacuum baking mechanisms, and more particularly, to a vacuum baking mechanism with buffer treatment and vacuum baking method thereof.

### 2. Description of the Related Art

In semiconductor manufacturing equipment nowadays, the semiconductor equipment transports substrates between different chambers to perform different treatments, such as etching, coating, cleaning, and cooling, on the substrates. However, before the substrate enters the chamber, when the substrate is in contact with the air in the atmospheric environment, the moisture in the air may be attached to the surface of the substrate, so as to affect the yield of the subsequent substrate processing treatment.

Generally, to resolve the negative impact on the yield of subsequent processes caused by moisture or residue formed on the substrate, the substrate is previously vacuum baked in a vacuum oven and then transported to the subsequent processing machine. In the method of vacuum baking, a plurality of substrates is placed into the vacuum oven; next, the gate is closed, and the air is removed from the vacuum oven; then, the heating process is performed to remove the moisture or residue on the substrates. When the baking process is completed, the gate is opened, and the substrates are taken out to be transported to the subsequent processing machine for subsequent processing operation. However, during such method, several issues are caused.

To achieve the vacuum condition, it takes a long time for the vacuum oven to remove the air. Also, when the substrate is to be taken out, a vacuum relief treatment has to be performed. Such vacuuming and vacuum relieving cycle has to be repeatedly carried out for each batch of substrates to undergo the baking process, causing a significant time consumption and greatly lowering the usage efficiency of the vacuum oven.

When each batch of substrates is input and output from the oven, the heating and cooling processes have to be repeatedly carried out, causing a significant time consumption and greatly lowering the usage efficiency of the vacuum oven as well.

In subsequent processes, the substrates will be processed one by one. Therefore, when the vacuum baked substrates are waiting to be processed, the moisture may be attached to the substrate again, thereby lowering the effect of the vacuum baking process.

Based on the reasons above, the conventional method by use of vacuum oven fails to achieve an optimal efficiency and effectiveness. Therefore, it is desirable for the industry to improve the aforementioned issues.

### SUMMARY OF THE DISCLOSURE

The present disclosure aims at resolving the issues of the low efficiency and moisture reattachment situation caused by the conventional vacuum oven.

For achieving the issues above, the present disclosure provides a vacuum baking mechanism with buffer treatment, the vacuum baking mechanism being connected with a processing mechanism to bake a plurality of substrates, the vacuum baking mechanism comprising: a substrate transport station, a first buffer chamber, and a vacuum baking chamber. The substrate transport station is disposed neighboring the processing mechanism. The substrate transport station comprises a transport conveyance module for taking and placing the substrates. The first buffer chamber is disposed neighboring the substrate transport station. The first buffer chamber comprises a first buffer gate, a plurality of first conveyance modules vertically stacked at intervals, and a first baking doorway. The first buffer gate is disposed neighboring the substrate transport station. The substrates enter and leave the first buffer chamber through the first buffer gate. The first conveyance modules are disposed between the first buffer gate and the first baking doorway for respectively receiving or outputting each substrate through the first buffer gate or the first baking doorway, and a first vacuuming module carries out a vacuuming operation when the first buffer gate is closed. The vacuum baking chamber is in communication with the first buffer chamber. The vacuum baking chamber comprises a first baking gate connected with the first baking doorway and a baking module. The first baking gate controls the communication between the vacuum baking chamber and the first buffer chamber. The baking module carries out a vacuum baking operation on the substrates.

In another embodiment of the present disclosure, a vacuum baking method of the vacuum baking mechanism is provided for carrying out a baking operation on the plurality of substrates. The vacuum baking method comprising step S1, step S2, and step S3. In step S1, the first buffer gate is opened, and the inputted substrates are placed into the first buffer chamber through the transport conveyance module, so that the substrates are respectively placed on the first conveyance modules. When the first buffer gate is closed, the first vacuuming module vacuums the first buffer chamber. In step S2, the first baking gate is opened, the substrates are placed into the baking module by the first conveyance modules, and the first baking gate is closed, such that the baking module carries out a vacuum baking operation on the substrates. In step S3, the first baking gate is opened again, and the first conveyance modules take the baked substrates out from the vacuum baking chamber and place the substrates in the first buffer chamber.

With such configuration, the present disclosure achieves following features.

With the first buffer chamber applied as a buffer treatment of the vacuum baking chamber, the vacuum baking chamber is prevented from directly contacting the atmospheric environment, after which the vacuum baking chamber has to undergo the vacuuming operation again when the next batch of substrates are to be baked, thereby lowering the preparation time needed for the vacuum baking chamber to perform the vacuum baking operation and improving the baking efficiency.

The first buffer chamber is applied as a cooling waiting area of the baked substrates, preventing the temperature of the vacuum baking chamber from significant reduction, so that the vacuum baking chamber does not need to undergo the heating operation again before the baking operation for the next batch of substrates. Therefore, the preparation time needed for the temperature rising and lowering process of the vacuum baking chamber is reduced.

With the first buffer chamber, the substrates taken out from the vacuum baking chamber are prevented from directly exposed in the atmospheric environment when waiting for subsequent process. Therefore, the time of the substrates exposed in the atmospheric environment is reduced, so as to reduce the possibility of the moisture reattachment on the substrates, thereby improving the processing yield and quality.

### BRIEF DESCRIPTION OF THE DRAWINGS

FIG. 1 is a top view of the vacuum baking mechanism in accordance with the first embodiment of the present disclosure.

FIG. 2 is a sectional view of the right side of the vacuum baking mechanism in accordance with the first embodiment of the present disclosure.

FIG. 3 is a top view of the vacuum baking mechanism in accordance with the second embodiment of the present disclosure.

FIG. 4 is a sectional side view of the substrate transport station and the second buffer chamber in accordance with the second embodiment of the present disclosure.

FIG. 5 is a sectional side view of the second buffer chamber and the vacuum baking chamber in accordance with the second embodiment of the present disclosure.

FIG. 6 is a flow chart of the vacuum baking method in accordance with an embodiment of the present disclosure.

FIG. 7 is a flow chart of the vacuum baking method in accordance with another embodiment of the present disclosure.

### DETAILED DESCRIPTION OF THE DISCLOSURE

The aforementioned and further advantages and features of the present disclosure will be understood by reference to the description of the preferred embodiment in conjunction with the accompanying drawings where the components are illustrated based on a proportion for explanation but not subject to the actual component proportion.

Embodiments of the present disclosure are illustrated in detail along with the drawings. However, the technical features included by the present disclosure are not limited to certain embodiments hereby provided. Scope of the present disclosure shall be referred to the claims, which include all the possible replacements, modifications, and equivalent features.

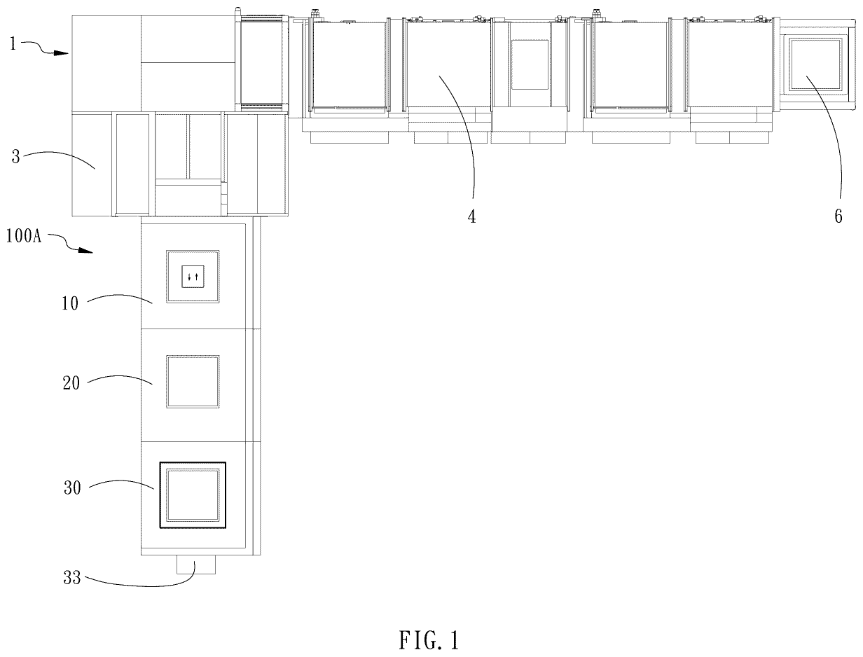

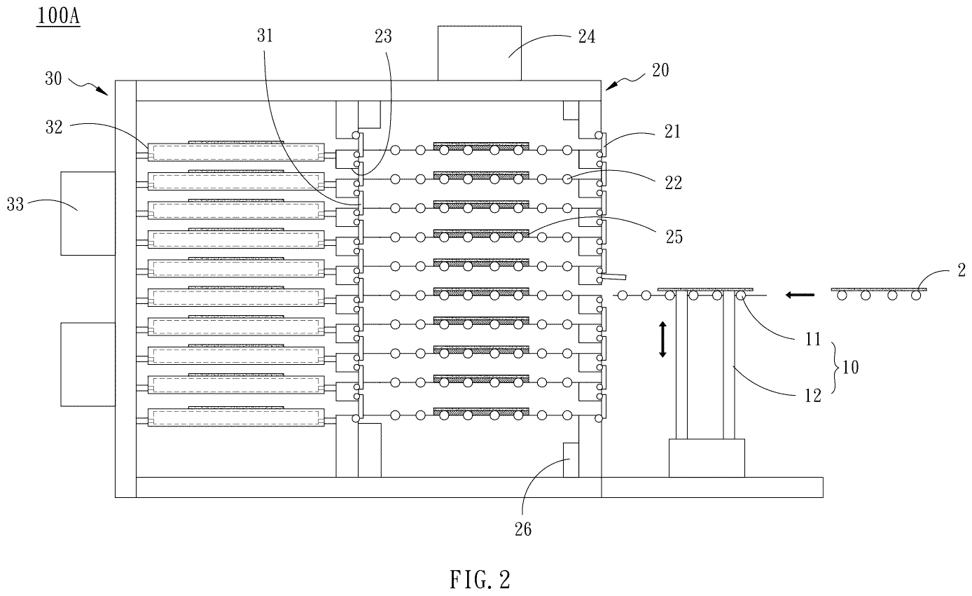

Referring to FIG. 1 to FIG. 2, in the embodiment, the present disclosure provides a vacuum baking mechanism 100A with buffer treatment, which is connected with a processing mechanism 1 to carry out a baking operation on a plurality of substrates 2. The vacuum baking mechanism 100A comprises a substrate transport station 10, a first buffer chamber 20, and a vacuum baking chamber 30. The processing mechanism 1 above is configured to, for example but not limited to, carry out coating, etching, and cleaning operations, so as to be formed with a plurality of mechanisms, chambers, or stations that are in communication with each other. The processing mechanism 1, in the embodiment, is a continuous processing equipment, which is allowed to comprise an input station 3, a plurality of processing chambers 4 connected in series, and an output station 6. The substrates 2 are able to be performed with coating, etching, and cleaning operations through those stations or chambers. However, the present disclosure is not limited to the configuration which is connected with a continuous processing equipment. In the embodiment, the substrate 2 is allowed to be a wafer, chip, or circuit board (such as PCB), etc.

In the embodiment of the vacuum baking mechanism 100A, the substrate transport station 10 is disposed neighboring the processing mechanism 1. In particular, the neighboring arrangement here, compared with other modules in the present disclosure, means that the substrate transport station 10 is arranged in a closer distance with respect to the processing mechanism 1 for facilitating the placing and taking operations, instead of indicating a physically neighboring relationship therebetween. The substrate transport station 10 comprises a transport conveyance module 11 and a vertical movement module 12. The transport conveyance module 11 is connected with the vertical movement module 12. The transport conveyance module 11 is disposed between the processing mechanism 1 and the first buffer chamber 20 to take out or place the substrates 2. The vertical movement module 12 controls the vertical movement of the transport conveyance module 11 in the substrate transport station 10, whereby the substrates 2 are distributed into the first buffer chamber 20.

In an embodiment of the present disclosure, the transport conveyance module 11 comprises a plurality of conveyance rollers disposed corresponding to two sides of the substrates 2 to convey the substrates 2. In an embodiment of the present disclosure, the power source of the vertical movement module 12 is allowed to be, for example but not limited to, a servo motor, stepper motor, pneumatic cylinder, or hydraulic cylinder, etc. In another embodiment, the transport conveyance module 11 is allowed to be a mechanical arm (such as 6-axis robotic arm), so as to carry out the substrates 2 taking or placing operations between the processing mechanism 1 and the first buffer chamber 20.

The first buffer chamber 20 is disposed neighboring the substrate transport station 10. In other words, the substrate transport station 10 is arranged between the processing mechanism 1 and the first buffer chamber 20. The first buffer chamber 20 receives the substrates 2 from the substrate transport station 10. The first buffer chamber 20 comprises a first buffer gate 21, a plurality of first conveyance modules 22 vertically stacked at intervals, a first baking doorway 23, and a first vacuuming module 24.

The first buffer gate 21 is disposed neighboring the substrate transport station 10. The first buffer gate 21 controls the communication between the substrate transport station 10 and the first buffer chamber 20, the substrates 2 enter and leave the first buffer chamber 20 through the first buffer gate 21. In the embodiment, the first buffer gate 21 pivotally opens and closes, allowing the substrates 2 to enter and leave the first buffer chamber 20. Also, the first buffer gate 21 is allowed to open through lateral sliding or vertical movement, such that the substrates 2 pass through the first buffer gate 21. Therefore, the opening and closing of the first buffer gate 21 is not limited to the pivotal movement.

The first baking doorway 23 is disposed neighboring the vacuum baking chamber 30. The first conveyance modules 22 are disposed between the first buffer gate 21 and the first baking doorway 23 for respectively receiving or outputting each substrate 2 through the first buffer gate 21 or the first baking doorway 23. In other words, the substrates 2 are allowed to move between the substrate transport station 10, the first buffer chamber 20, and the vacuum baking chamber 30. In an embodiment, the first conveyance modules 22 comprise a plurality of, for example but not limited to, conveyance rollers for conveying the substrates 2. When the substrates 2 are placed in the first buffer chamber 20, the first buffer gate 21 closes, and the first vacuuming module 24 carries out the vacuuming operation, whereby the first buffer chamber 20 is in a vacuum status, preventing the substrates 2 from contacting the air. In a preferred embodiment, the pressure value in the first buffer chamber 20 ranges from 1×10⁻¹ torrs to 1×10⁻³ torrs.

In an embodiment, a plurality of first buffer gates 21 are included. Each of the first buffer gates 21 is disposed in positional alignment with each of the first conveyance modules 22, such that the substrates 2 are respectively inputted and outputted. Such configuration achieves the advantage that the first buffer chamber 20 is able to independently open and close the first buffer gates 21 for the placing and taking operation of one of the substrates 2. Respectively opening each of the first buffer gates 21 prevents excessive air from entering the first buffer chamber 20, so that the first buffer chamber 20 is easier to maintain the isolation status thereof, thereby reducing the contact between the substrates 2 and external air.

The vacuum baking chamber 30 is in communication with the first buffer chamber 20 to receive the substrates 2 from the first buffer chamber 20 or outputting the substrates 2 to the first buffer chamber 20. The vacuum baking chamber 30 comprises a first baking gate 31 connected with the first baking doorway 23, and a baking module 32. The first baking gate 31 controls the communication between the vacuum baking chamber 30 and the first buffer chamber 20, so that the first conveyance modules 22 convey the substrates 2 to the vacuum baking chamber 30, allowing the baking module 32 to bake the substrates 2. In an embodiment of the present disclosure, a plurality of baking modules 32 are included and disposed in a stacked arrangement at intervals respectively corresponding to the first conveyance modules 22, so that each baking module 32 is configured to independently bake a single substrate 2. Further, the baking modules 32 are able to bake the substrates 2 through thermal radiation.

In an embodiment, the vacuum baking chamber 30 further comprises a second vacuuming module 33 for carrying out the vacuuming operation of the vacuum baking chamber 30, such that the vacuum baking chamber 30 is in the vacuum status to vacuum bake the substrates 2. In a preferred embodiment, the pressure value in the vacuum baking chamber 30 is allowed to range from 1×10⁻² torrs to 1×10⁻⁸ torrs, wherein the vacuum level of the vacuum baking chamber 30 has to be greater than that of the first buffer chamber 20.

A practical operation status is provided as an example for illustration here. When the substrate transport station 10 orderly inputs the substrates 2 into the first buffer chamber 20, the first buffer gate 21 closes, and the first vacuuming module 24 carries out a low-level vacuuming operation of the first buffer chamber 20. Next, the first baking gate 31 opens, and the first conveyance module 22 inputs all the substrates 2 into the vacuum baking chamber 30 all at once. After that, the first baking gate 31 closes, and the second vacuuming module 33 carries out the vacuuming operation, and the baking module 32 carries out the baking operation, thereby achieving the vacuum baking operation of the substrates 2. Notably, the vacuum baking chamber 30 itself is already in the vacuum status. The opening of the first baking gate 31 will cause the communication between the vacuum baking chamber 30 and the first buffer chamber 20, lowering the vacuum level of the vacuum baking chamber 30. However, after all the substrates 2 are inputted into the vacuum baking chamber 30 and the first baking gate 31 closes, the second vacuuming module 33 is applied to carry out a reinforcing vacuuming operation, so as to improve the vacuum level of the vacuum baking chamber 30 to a higher vacuum level. After the completion of the baking operation of all the substrates 2, the first baking gate 31 opens, and the first conveyance module 22 receives the substrates 2 in the vacuum baking chamber 30 all at once, such that the first buffer chamber 20 finishes the receiving operation of the substrates 2. Finally, the substrates 2 are moved to the substrate transport station 10 one-by-one from the first buffer chamber 20, allowing the substrate transport station 10 to carry out the subsequent substrates 2 outputting operation.

In an embodiment of the present disclosure, the first buffer chamber 20 further comprises a first cooling module 25 disposed on one side of the first conveyance module 22 neighboring the substrate 2 for cooling the baked substrates 2, thereby reducing the cooling buffer time of the substrates 2. In the embodiment, the first cooling module 25 carries out the cooling operation through contact cooling or non-contact cooling, such as air cooling, water cooling, or using a cooling plate.

In an embodiment of the present disclosure, the first buffer chamber 20 comprises a first nitrogen module 26 disposed between the first buffer gate 21 and the first baking doorway 23 for spraying gas on the substrates 2. For example, when the substrates 2 are outputted from the first buffer gate 21, the first nitrogen module 26 sprays low-temperature nitrogen on the substrates 2, so as to form a protection film on the surface of the substrates 2, thereby postponing or reducing the time or chance of the moisture in the air being re-attached to the substrates 2 after the substrates 2 leave the first buffer chamber 20. Also, the first nitrogen module 26 cools the baked substrates 2 as well, reducing the cooling time of the substrates 2.

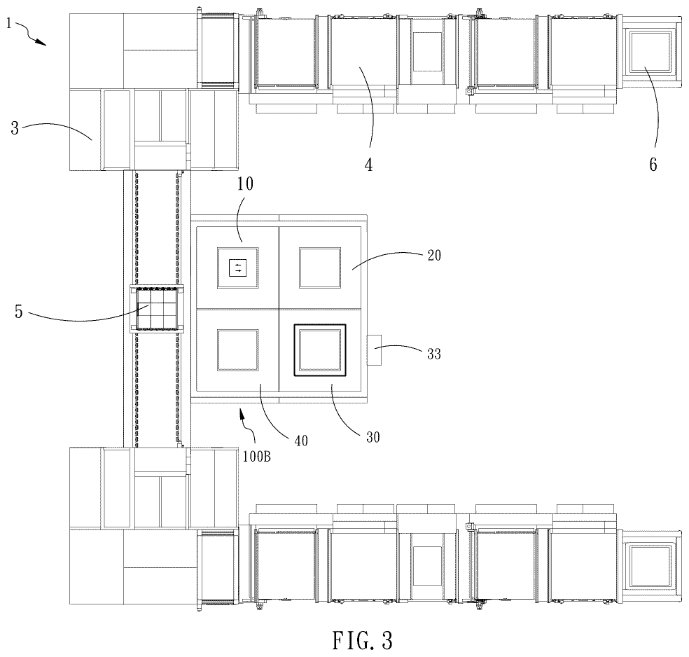

Referring to FIG. 3 to FIG. 5, an embodiment of a vacuum baking mechanism 100B is illustrated. The difference between the vacuum baking mechanism 100B and the vacuum baking mechanism 100A lies in that the vacuum baking mechanism 100B further comprises a second buffer chamber 40. The vacuum baking mechanism 100B is connected with a delivery mechanism 5, wherein the delivery mechanism 5 is disposed between and neighboring two input stations 3 of the processing mechanism 1, so as to deliver the substrates 2 between the two input stations 3 and the vacuum baking mechanism 100B. In the embodiment, the substrate transport station 10, the first buffer chamber 20, the second buffer chamber 40, and the vacuum baking chamber 30 are formed in a cube or cuboid. The first buffer chamber 20 and the second buffer chamber 40 are disposed on two neighboring lateral sides of the substrate transport station 10, respectively. Also, the first buffer chamber 20 and the second buffer chamber 40 are respectively connected with two neighboring lateral sides of the vacuum baking chamber 30, such that the substrate transport station 10, the first buffer chamber 20, the second buffer chamber 40, and the vacuum baking chamber 30 are disposed in a 2*2 grid arrangement. Therefore, when the substrates 2 are taken out from or placed in one of the first buffer chamber 20 and the second buffer chamber 40, the other buffer chamber is allowed to carry out the cooling buffer or baking operation of the substrates 2. Alternatively, when one of the first buffer chamber 20 and the second buffer chamber 40 is waiting to take out the substrates 2 that are being baked, the other buffer chamber is allowed to input other substrates 2 from the substrate transport station 10. With such configuration, the two buffer chambers input or output the substrates 2 at different timings, so as to reduce the idling time of the vacuum baking chamber 30 and improve the overall operation efficiency.

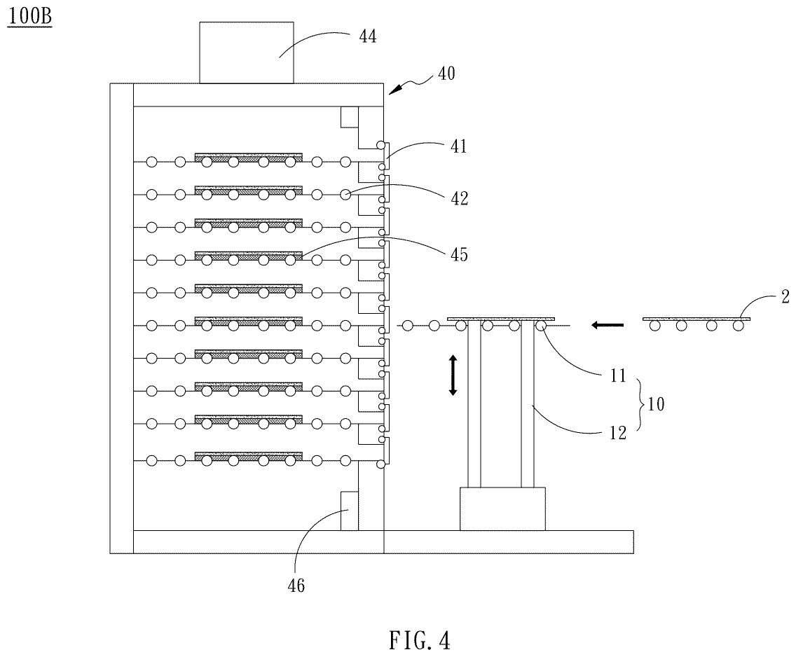

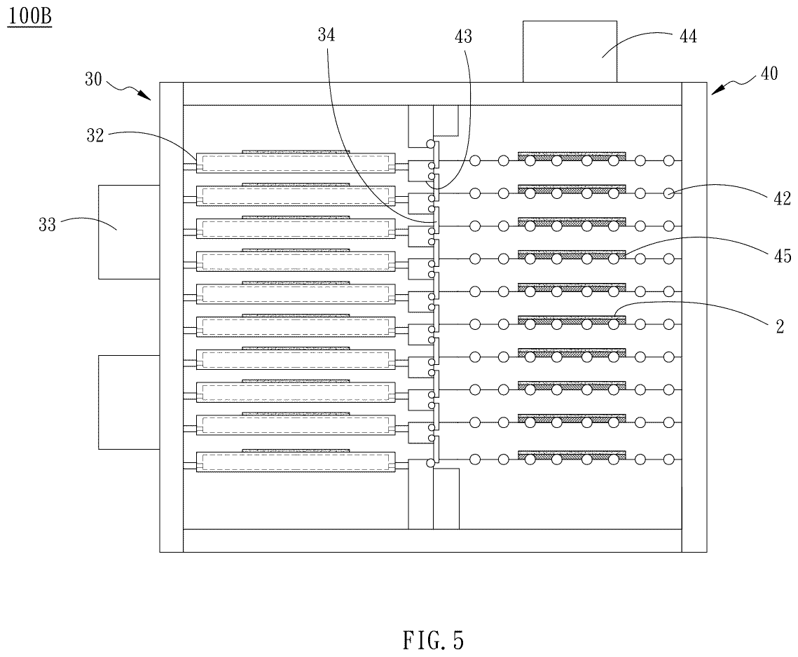

In an embodiment of the present disclosure, referring to FIG. 4 and FIG. 5, which are the rear-side sectional view and the right-side sectional view of the second buffer chamber 40, respectively. The second buffer chamber 40 neighbors the substrate transport station 10 (as shown by FIG. 4), and the second buffer chamber 40 is in communication with the vacuum baking chamber 30 (as shown by FIG. 5). The second buffer chamber 40 receives the substrates 2 from the substrate transport station 10. The second buffer chamber 40 comprises a second buffer gate 41, a plurality of second conveyance modules 42 vertically stacked at intervals, a second baking doorway 43, and a third vacuuming module 44.

The second buffer gate 41 neighbors the substrate transport station 10. The second buffer gate 41 controls the communication between the substrate transport station 10 and the second buffer chamber 40. The substrates 2 enter and leave the second buffer chamber 40 through the second buffer gate 41. The second conveyance modules 42 are disposed in positional alignment with the entering and leaving positions of the substrates 2, so as to respectively receive or output each substrate 2 through the second buffer gate 41 or the second baking doorway 43. In an embodiment, the second conveyance modules 42 comprise a plurality of conveyance rollers for conveying the substrates 2. However, the present disclosure is not limited to such configuration. The second buffer gate 41, the second conveyance module 42, the second baking doorway 43, and the third vacuuming module 44 are functionally identical to the first buffer gate 21, the first conveyance module 22, the first baking doorway 23, and the first vacuuming module 24, respectively.

In an embodiment of the present disclosure, the vacuum baking chamber 30 further comprises a second baking gate 34 connected with the second baking doorway 43. The second baking gate 34 controls the communication between the vacuum baking chamber 30 and the second buffer chamber 40, such that the second conveyance modules 42 convey the substrates 2 to the vacuum baking chamber 30, whereby the baking module 32 vacuum bakes the substrates 2.

In an embodiment of the present disclosure, the second buffer chamber 40 further comprises a second cooling module 45 disposed on one side of the second conveyance module 42 neighboring the substrate 2 for cooling the baked substrates 2. In the embodiment, the second cooling module 45 carries out the cooling operation through contact cooling or non-contact cooling, such as air cooling, water cooling, or using a cooling plate.

In an embodiment of the present disclosure, a plurality of second buffer gates 41 is included and disposed in positional alignment with the second conveyance modules 42, so as to wholly or respectively input or output the substrates 2. Therein, the operation status and effects of the second buffer gate 41 are identical to those of the first buffer gate 21, so that the relative descriptions are omitted here.

In an embodiment of the present disclosure, the second buffer chamber 40 comprises a second nitrogen module 46 disposed between the second buffer gate 41 and the second baking doorway 43 for spraying gas on the substrates 2. Therein, the operation status and effects of the second nitrogen module 46 are identical to those of the first nitrogen module 26, so that the relative descriptions are omitted here.

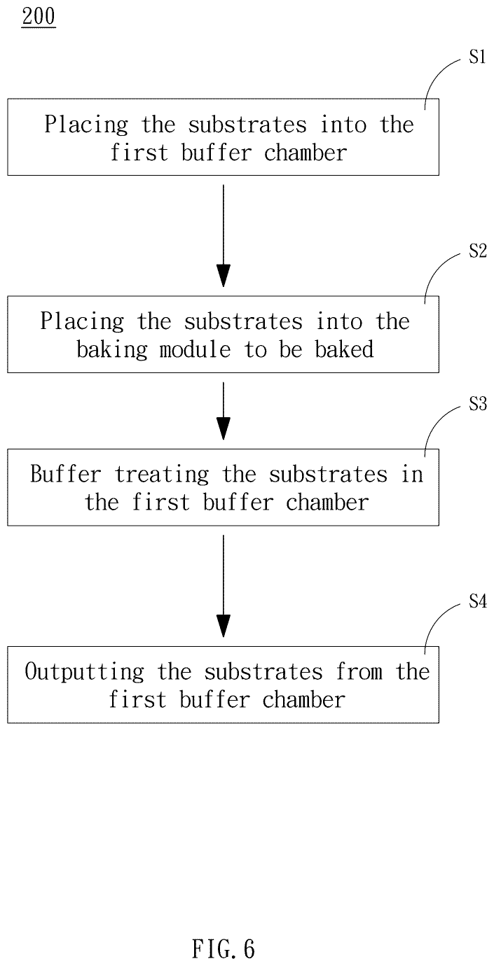

Referring to FIG. 6, in another embodiment of the present disclosure, a vacuum baking method 200 of the vacuum baking mechanism 100A, 100B is provided for baking a plurality of substrates 2. The vacuum baking method 200 comprises steps S1 to S3.

In step S1, the first buffer gate 21 is opened, and the inputted substrates 2 are placed into the first buffer chamber 20 through the transport conveyance module 11, so that the substrates 2 are respectively placed on the first conveyance modules 22. When the first buffer gate 21 is closed, the first vacuuming module 24 vacuums the first buffer chamber 20. In step S2, the first baking gate 31 is opened, the substrates 2 are placed into the baking module 32 by the first conveyance modules 22, and the first baking gate 31 is closed, such that the baking module 32 carries out a vacuum baking operation on the substrates 2. In step S3, the first baking gate 31 is opened again, and the first conveyance modules 22 take the baked substrates 2 out from the vacuum baking chamber 30 and place the substrates 2 in the first buffer chamber 20.

In an embodiment of the present disclosure, a step S4 is further included after step S3. In Step S4, the first buffer gate 21 is opened, and one of the substrates 2 or all the substrates 2 are outputted. Then, the first nitrogen module 26 disposed in the first buffer chamber 20 sprays gas on the baked substrates 2. After step S4, the first buffer chamber 20 repeats the operation from step S1, S2, S3, to S4. The embodiment achieves an advantage that the first nitrogen module 26 forms a protection film on the surface of the substrates 2, thereby postponing or reducing the time or chance of the moisture in the air being re-attached to the substrates 2.

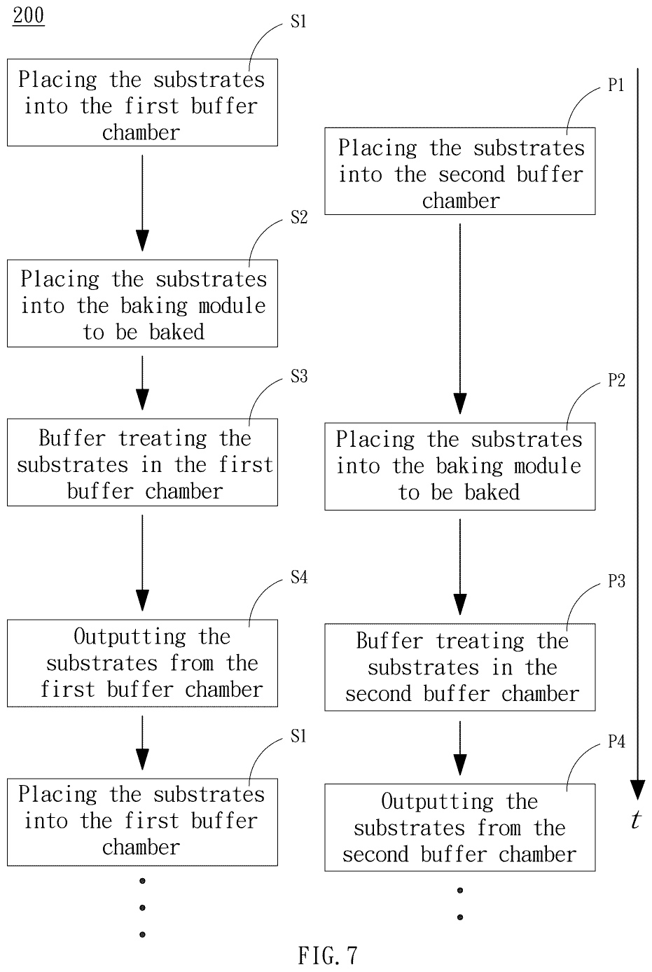

Referring to FIG. 7, a schematic view illustrating the timing flow of the vacuum baking method 200 is provided. In another embodiment of the present disclosure, a step P1 is further included after step S1. In step P1, the second buffer gate 41 is opened, and the transport conveyance module 11 continuously inputs another batch of the substrates 2 into the second buffer chamber 40, whereby the substrates 2 are respectively placed on the second conveyance modules 42. When the second buffer gate 41 is closed, the third vacuuming module 44 vacuums the second buffer chamber 40. However, the present disclosure does not limit the order of step P1, step S2, and step S3 to be identical to the order shown in FIG. 7. In other words, step P1 is allowed to be placed before or after step S2 and step S3; or, step P1 is allowed to be placed between step S2 and step S3. A practical operation status is provided as an example for illustration here. After the substrates 2 are placed into the first buffer chamber 20, when the first buffer chamber 20 carries out the vacuuming operation, another batch of substrates 2 are allowed to be moved to the second buffer chamber 40 from the substrate transport station 10, thereby improving the overall operation efficiency.

In an embodiment of the present disclosure, a step P2 is further included after step S3. In step P2, the second baking gate 34 is opened, and the second conveyance modules 42 place the substrates 2 into the baking module 32. Then, the second baking gate 34 is closed, so that the baking module 32 carries out the vacuum baking operation on the substrates 2.

In an embodiment of the present disclosure, a step P3 is further included after step P2. In step P3, the first buffer gate 21 is opened, and the transport conveyance module 11 continues to input another batch of the substrates 2 on the first conveyance modules 22. Then, the second baking gate 34 is opened again, and the second conveyance modules 42 take out the baked substrates 2 from the vacuum baking chamber 30 and place the substrates 2 into the second buffer chamber 40. However, the present disclosure does not limit the order of step P2, step P3, and step S4 to be identical to the order shown in FIG. 7. In other words, step S4 is allowed to be placed before or after step P2 and step P3; or, step S4 is allowed to be placed between step P2 and step P3. A practical operation status is provided as an example for illustration here. After the baked substrates 2 are placed into the first buffer chamber 20, when the first buffer chamber 20 moves the substrates 2 to the substrate transport station 10 one-by-one, the substrates 2 in the second buffer chamber 40 are allowed to be moved to the idling baking module 32. The first buffer chamber 20 and the second buffer chamber 40 input or output different batches of the substrates 2 at different timings, so as to improve the overall operation efficiency.

In an embodiment of the present disclosure, a step P4 is further included after step P3. In step P4, the second buffer gate 41 is opened to output one of the substrates 2 or all the substrates 2, and the second nitrogen module 46 sprays gas on the baked substrates 2. However, the present disclosure does not limit the order of step S1, step P2, step P3, and step P4 to be identical to the order shown in FIG. 7. In other words, order of steps is allowed to be adjusted according to actual operation conditions. Notably, as shown by FIG. 7, the timeline is only used to illustrate the timing relationship from step S1 to step S4 and from step P1 to step P4. There is no such limitation such as that step S2 has to be carried out after step P1 or that step S4 has to be carried out after step P2.

With the foregoing configuration, the present disclosure achieves following technical features.

The first buffer chamber 20 is applied as a buffer treatment for the vacuum baking chamber 30, preventing the vacuum baking chamber 30 from direct contact with the atmospheric environment. Before the vacuum baking chamber 30 carries out the next baking operation on the next batch of substrates 2, the time duration needed to re-vacuum the vacuum baking chamber 30 is reduced, thereby improving the baking efficiency.

The first buffer chamber 20 is applied as a cooling waiting area for the baked substrates 2, preventing the vacuum baking chamber 30 from significant temperature reduction, which causes the necessity of re-heating operation when the vacuum baking chamber 30 is to bake the next batch of substrates 2. Therefore, the preparation time needed for the temperature rising and lowering process of the vacuum baking chamber 30 is reduced.

With the plurality of first buffer gates 21, the first buffer chamber 20 is able to independently open and close each first buffer gate 21, preventing excessive air from entering the first buffer chamber 20 when the first buffer gate 21 is opened, so that the first buffer chamber 20 is easier to maintain the isolation status thereof, thereby reducing the contact between the substrates 2 and external air, and further improving the production yield of the substrates 2.

With the cooperation between the first buffer chamber 20 and the second buffer chamber 40, the first buffer chamber 20 and the second buffer chamber 40 are able to input the substrates 2 for vacuum baking at different timings, thereby improving the overall operation efficiency.

Although particular embodiments of the disclosure have been described in detail for purposes of illustration, various modifications and enhancements may be made without departing from the spirit and scope of the disclosure. Accordingly, the disclosure is not to be limited except as by the appended claims.

What is claimed is:

1. A vacuum baking mechanism with buffer treatment connected with a processing mechanism for baking a plurality of substrates, the vacuum baking mechanism comprising:
a substrate transport station neighboring the processing mechanism, the substrate transport station comprising a transport conveyance module for taking and placing the substrates;
a first buffer chamber neighboring the substrate transport station, the first buffer chamber comprising a first buffer gate, a plurality of first conveyance modules vertically stacked at intervals, a first baking doorway, and a first vacuuming module, the first buffer gate neighboring the substrate transport station, the substrates entering and leaving the first buffer chamber through the first buffer gate, the first conveyance modules being disposed between the first buffer gate and the first baking doorway for respectively receiving or outputting each of the substrates through the first buffer gate or the first baking doorway, the first vacuuming module carrying out a vacuuming operation when the first buffer gate is closed; and
a vacuum baking chamber connected with the first buffer chamber, the vacuum baking chamber comprising a first backing gate connected with the first baking doorway and a baking module, the first baking gate controlling a communication between the vacuum baking chamber and the first buffer chamber, the baking module vacuum baking the substrates.

2. The vacuum baking mechanism with buffer treatment of claim 1, wherein the substrate transport station further comprises a vertical movement module connected with the transport conveyance module; the vertical movement module controls the transport conveyance module to vertically move in the substrate transport station.

3. The vacuum baking mechanism with buffer treatment of claim 1, wherein a plurality of the first buffer gates is included; the first buffer gates are disposed in positional alignment with the first conveyance modules, respectively.

4. The vacuum baking mechanism with buffer treatment of claim 1, wherein the first buffer chamber further comprises a first cooling module for cooling the substrates.

5. The vacuum baking mechanism with buffer treatment of claim 1, wherein the first buffer chamber comprises a first nitrogen module disposed between the first buffer gate and the first baking doorway for spraying a gas on the substrates.

6. The vacuum baking mechanism with buffer treatment of claim 1, wherein a second buffer chamber is further included to be disposed neighboring the substrate transport station and connected with the vacuum baking chamber;
the second buffer chamber comprises a second buffer gate, a plurality of second conveyance modules vertically stacked at intervals, a second baking doorway, and a third vacuuming module; the second buffer gate is disposed neighboring the substrate transport station; the substrates enter and leave the second buffer chamber through the second buffer gate; the second conveyance modules are disposed in positional alignment with the substrates for receiving or outputting the substrates through the second buffer gate or the second baking doorway, respectively; the third vacuuming module carries out a vacuuming operation when the second buffer gate is closed.

7. The vacuum baking mechanism with buffer treatment of claim 6, wherein the substrate transport station, the first buffer chamber, the second buffer chamber, and the vacuum baking chamber are formed in a cube or cuboid; the first buffer chamber and the second buffer chamber are disposed on two neighboring sides of the substrate transport station, respectively, and the first buffer chamber and the second buffer chamber are connected with two neighboring sides of the vacuum baking chamber, respectively, such that the substrate transport station, the first buffer chamber, the second buffer chamber, and the vacuum baking chamber are disposed in a 2*2 grid arrangement.

8. The vacuum baking mechanism with buffer treatment of claim 6, wherein the vacuum baking chamber further comprises a second baking gate connected with the second baking doorway; the second baking gate controls a communication between the vacuum baking chamber and the second buffer chamber.

9. The vacuum baking mechanism with buffer treatment of claim 6, wherein the second buffer chamber further comprises a second cooling module for cooling the substrates.

10. The vacuum baking mechanism with buffer treatment of claim 6, wherein a plurality of the second buffer gates is included and disposed in positional alignment with the second conveyance modules.

11. The vacuum baking mechanism with buffer treatment of claim 6, wherein the second buffer chamber comprises a second nitrogen module disposed between the second buffer gate and the second baking doorway for spraying a gas on the substrates.

12. A vacuum baking method using the vacuum baking mechanism of claim 1 for baking the substrates, the vacuum baking method comprising following steps:
step S1: the first buffer gate is opened, and the inputted substrates are placed into the first buffer chamber through the transport conveyance module, so that the substrates are respectively placed on the first conveyance modules; when the first buffer gate is closed, the first vacuuming module vacuums the first buffer chamber;
step S2: the first baking gate is opened, the substrates are placed into the baking module by the first conveyance modules; then, the first baking gate is closed, and the baking module carries out a vacuum baking operation on the substrates; and
step S3; the first baking gate is opened again, and the first conveyance modules take the baked substrates out from the vacuum baking chamber and place the substrates in the first buffer chamber.

13. The vacuum baking method using the vacuum baking mechanism of claim 12, wherein a step S4 is further included after step S3; in step S4, the first buffer gate is opened, and one of the substrates or all the substrates are outputted; then, a first nitrogen module disposed in the first buffer chamber sprays a gas on the baked substrates.

14. The vacuum baking method using the vacuum baking mechanism of claim 12, wherein a step P1 is further included after step S1; in step P1, a second buffer gate neighboring the substrate transport station is opened, and the transport conveyance module continuously inputs another batch of the substrates into a second buffer chamber which disposed neighboring the substrate transport station and connected with the vacuum baking chamber, whereby the substrates are respectively placed on a plurality of second conveyance modules vertically stacked at intervals; when the second buffer gate is closed, a third vacuuming module vacuums the second buffer chamber.

15. The vacuum baking method using the vacuum baking mechanism of claim 14, wherein a step P2 is further included after step S3; in step P2, a second baking gate controlling a communication between the vacuum baking chamber and the second buffer chamber is opened, and the second conveyance modules place the substrates into the baking module; then, the second baking gate is closed, and the baking module carries out a vacuum baking operation on the substrates.

16. The vacuum baking method using the vacuum baking mechanism of claim 15, wherein a step P3 is further included after step P2; in step P3, the first buffer gate is opened, and the transport conveyance module continues to input another batch of the substrates on the first conveyance modules; then, the second baking gate is opened again, and the second conveyance modules take out the baked substrates from the vacuum baking chamber and place the substrates into the second buffer chamber.

17. The vacuum baking method using the vacuum baking mechanism of claim 16, wherein a step P4 is further included after step P3; in step P4, the second buffer gate is opened to output one of the substrates or all the substrates, and a second nitrogen module disposed in the second buffer chamber sprays a gas on the baked substrates.
